(19) United States
(12) Patent Application Publication
(10) Pub. No.: US 2005/0102391 A1
(43) Pub. Date: May 12, 2005

(54) Method and apparatus providing an asymmetric ping procedure

(76) Inventors: Ville Ruutu, Espoo (FI); Jussi Ruutu, Espoo (FI)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(21) Appl. No.: 10/705,676

(22) Filed: Nov. 10, 2003

(51) Int. Cl. G06F 15/173; G01R 25/00

(52) U.S. Cl. 709/224; 702/79

(57) ABSTRACT

A method (and corresponding equipment) for determining either a downlink delay in communicating packets via a packet-conveying network from a sender (11) to a receiver (12) or the corresponding uplink delay, or both, but separately from each other, the method including: steps (21 22 23 24) in which the sender (11) and receiver (12) exchange a first and second pair of packets (14a-b 15a-b) consisting of respective first and second uplink packets (14a 15a) and a first and second downlink packets (14b 15b), and also determines round trip times (t_A t_B) for the two exchanges; with the exchanges made using packet sizes such that at least either the first and second uplink packets (14a 15a) or the first and second downlink packets (14b 15b) differ in size from each other.

### TECHNICAL FIELD

The present invention pertains to the field of packet data networks. More particularly, the present invention pertains to the problem of measuring reliably the transfer delays (and simultaneously, available bandwidth) both for uplink and downlink between two communicating devices.

### BACKGROUND ART

A problem in the communication of packets between nodes of a telecommunications network is how to measure uplink and downlink data packet transfer delays and capacities separately, based on simple round-trip time measurements when the network is asymmetric, i.e. when the capacities (and related transfer delays) are different in uplink and downlink. Such networks include, e.g. Asymmetric Digital Subscriber Line (ADSL), General Packet Radio Service (GPRS) and satellite networks. Moreover, the public Internet features typically certain asymmetric behavior, e.g. due to changing routes and traffic congestion in IP (internet protocol) routers.

So far it has not been possible to measure in a simple way separately the uplink and downlink transfer delays, only the sum of both, i.e. round-trip time. The most well-known example of such a measurement is the widely-used ping-function-based measurement of TCP/IP (transmission control protocol/internet protocol) networks. (Using the ping function available for TCP/IP networks, a destination is in effect pinged by sending a packet to the destination, and the pinged destination provides a ping response (another packet) if it is able to be reached. The time between sending the ping packet and the arrival back of the ping-response packet is provided by the ping function.)

Besides the ping-function measurement of round trip time, to provide a time for communicating from one node to another (and not assuming it is the same as communicating in the other direction), there have only been complicated methods that involve delivering an exact time signal to both ends of a communication path, e.g. with specialized hardware such as hardware using a Global Positioning System (GPS) time signal.

What is therefore needed is a reasonably simple way to measure the time for a packet to reach a node in a telecommunications network that is asymmetric, ideally a way that does not require specialized equipment.

### DISCLOSURE OF THE INVENTION

Accordingly, in a first aspect of the invention, a method is provided for determining a downlink delay in communicating packets via a packet-conveying network from a sender to a receiver or an uplink delay for communicating packets from the receiver to the sender, or both the downlink delay and also the uplink delay, or for determining uplink or downlink capacities or both, the method comprising: a step in which the sender and receiver exchange a first pair of packets consisting of a first uplink packet and a first downlink packet and determine a round trip time for the exchange of the first pair of packets; and a step in which the sender and receiver exchange a second pair of packets consisting of a second uplink packet and a second downlink packet and determine a round trip time for the exchange of the second pair of packets; wherein at least either the first and second uplink packets or the first and second downlink packets differ in size.

In accord with the first aspect of the invention, the steps in which the sender and receiver exchange a pair of packets may be repeated with at least either the first and second uplink packets or the first and second downlink packets differing in size, and the round trip times for the respective exchanges may also again be determined, and the sender may then determine processed round trip times for each of the exchanges by performing a statistical analysis of the round trip times for the respective exchanges.

Also in accord with the first aspect of the invention, the method may further comprise: a step in which the sender determines for a packet of size S the uplink and downlink delays D_u and D_d, respectively, using:
D_{—}u=S(t_{—}A−t_{—}B)/(s_{—}uA−s_{—}uB),
and
D_{—}d=S[t_{—}B−d_{—}r−((s_{—}uB*(t_{—}A−t_{—}B))/(s_{—}uA−s_{—}uB))]/s_{—}d,
in which d_r is a receiver delay indicating a delay between when the receiver receives one of the downlink packets and when the receiver transmits the corresponding uplink packet in response, t_A is the round trip time for exchanging the first pair of packets of consisting of the first uplink packet having size s_uA and the first downlink packet having size s_d, and in which t_B is the round trip time for exchanging the second pair of packets of consisting of the second uplink packet having size s_uB and the second downlink packet having the same size as the first downlink packet, wherein s_uA is different than s_uB. Further, instead of the uplink packets in the first and second exchange of packets differing in size, the downlink packets may differ in size.

Also in accord with the first aspect of the invention, the method may further comprise: a step in which the sender determines the uplink and downlink capacities C_u and C_d, respectively, using:
C_{—}u=(s_{—}uA−s_{—}uB)/(t_{—}A−t_{—}B),
and
C_{—}d=s_{—}d/[t_{—}B−d_{—}r−((s_{—}uB*(t_{—}A−t_{—}B))/(s_{—}uA−s_{—}uB))],
in which t_A is the round trip time for exchanging the first pair of packets consisting of the first uplink packet having size s_uA and the first downlink packet having size s_d, and in which t_B is the round trip time for exchanging the second pair of packets consisting of the second uplink packet having size s_uB and the second downlink packet having the same size as the first downlink packet, wherein s_uA is different than s_uB. Further, instead of the uplink packets in the first and second exchange of packets differing in size, the downlink packets may differ in size.

Also in accord with the first aspect of the invention, a dynamical quantity may be associated with the delay estimates or with the capacity estimates and either the capacities or the delays or both may be estimated based on the dynamical quantity using already collected information about the capacities and the delays or both and also using the related dynamical quantity. Further, the dynamical quantity may be, e.g., the time of day, or both the time of day and the day of the week.

Also in accord with the first aspect of the invention, at least one of the packets may be used to convey information either of use in a predetermined protocol, or of use in determining a receiver delay quantity indicating a delay between when the receiver receives the downlink packet and when the receiver transmits the uplink packet in response.

In a second aspect of the invention, a computer program product is provided, comprising: a computer readable storage structure embodying computer program code thereon for execution by a computer processor in a sender device, with said computer program code comprising instructions for performing the steps of a method according to the first aspect of the invention.

In a third aspect of the invention, an apparatus is provided, adapted so as to be operative according to a method provided by the first aspect of the invention.

In a fourth aspect of the invention, a system is provided, comprising a telecommunication network, and a sender device and a receiver device communicatively coupled thereby, the sender including an apparatus according to the third aspect of the invention.

### BRIEF DESCRIPTION OF THE DRAWINGS

The above and other objects, features and advantages of the invention will become apparent from a consideration of the subsequent detailed description presented in connection with accompanying drawings, in which:

FIGS. 1A and 1B are in combination a schematic illustration of the asymmetric ping procedure provided by the invention.

FIG. 2 is a flow chart illustrating how to perform the asymmetric ping procedure provided by the invention.

FIG. 3 is a simplified block diagram of a telecommunication terminal having modules for performing the asymmetric ping procedure provided by the invention.

### BEST MODE FOR CARRYING OUT THE INVENTION

As explained below, to measure uplink and downlink transfer delays and capacities separately, the invention provides what can be called an asymmetric ping procedure, which makes round-trip time measurement at least twice, with different packet sizes in at least one of the two directions, e.g. the uplink, in what amounts to an asymmetric ping procedure. The different capacity (bandwidth) used by the different sized packets causes different transfer delay times. The invention provides two simple equations that yield the transfer delays separately for uplink and downlink, and also two simple equations for the uplink and downlink network capacities. Such a relatively simple procedure can be implemented in an end user device (such as a PC or a cell phone), providing reasonably accurate information about the delays and capacities of the telecommunications network, without requiring any special hardware. Possible use cases include enhancing the operation of Assisted-Global Positioning System (A-GPS) location systems, delivering accurate clocking to any TCP/IP device, and allowing end users the possibility of monitoring delays and capacities both in uplink and downlink separately. Various services and application can benefit from having a way to measure and monitor delays and capacities, including for example streaming media services, interactive audio and video applications, various network games, etc.

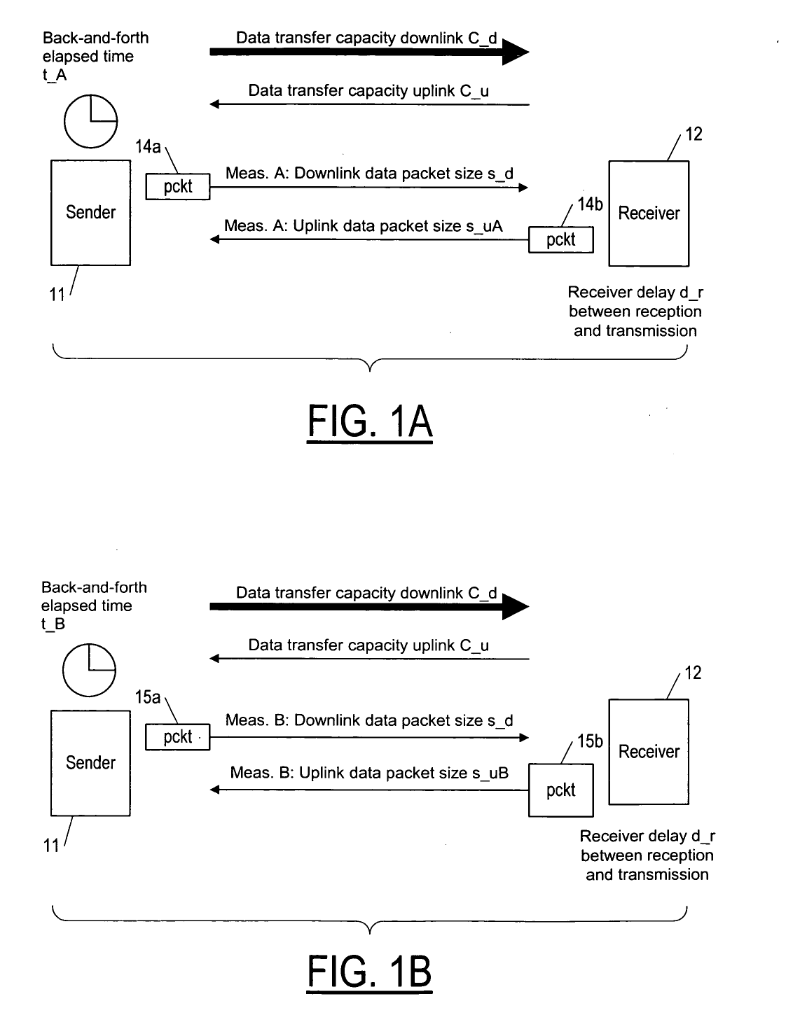

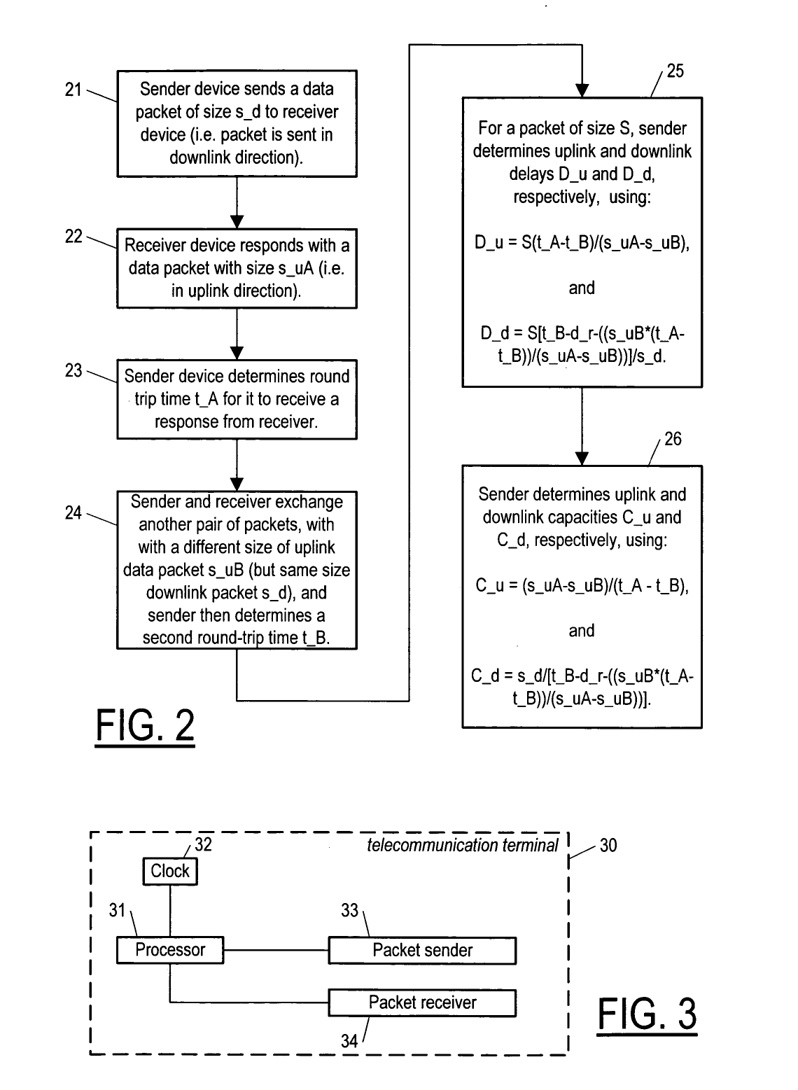

Referring now to FIGS. 1A, 1B, and 2, a method according to the invention for separately estimating both the uplink and downlink transfer delays for a packet of size S to be communicated between a sender 11 and a receiver 12 of a telecommunications network—i.e. of performing the asymmetric ping procedure provided by the invention, is shown as including a first step 21 in which the sender device 11 sends a data packet 14a of size s_d to the receiver device 12 (i.e. the packet is sent in the downlink direction, however, the name downlink is here just a descriptive name relative to sender and the sender can be, for example, either a mobile device or a server device). The method is intended for use in case of the telecommunication network having an asymmetric data transfer capacity, i.e. having a data transfer capacity for downlink C_d that is different than (and in FIGS. 1A-B illustrated as e.g. larger than) the data transfer capacity for uplink C_u; the method is also intended for use in cases when it is not known whether the telecommunication network has an asymmetric data transfer capacity or not. In a next step 22, the receiver device 12 responds with a data packet 14b of size s_uA (i.e. in uplink direction, again here uplink is defined relative to sender and should not be mixed with the meaning of uplink/downlink e.g. in a cellular network), after a receiver delay d_r between reception of the data packet 14a and transmission of the response packet 14b. The receiver delay d_r is assumed to be the same for the A and B cases, i.e. it is constant in time and independent of packet size. In some embodiments, it can be neglected because it is small. In others, it can be determined once and for all (by one or another means not the subject of the invention) and its value provided to the sender (once and for all).

In a next step 23, the sender device 11 determines the round trip time t_A for it to receive a response from receiver (by e.g. comparing the time of a local clock when the first packet 14a was sent and when the response packet 14b was received). In a next step 24, the sender and receiver devices exchange another pair of packets 15a 15b, with the uplink packet 15b having a different size s_uB compared to the size s_uA of the uplink packet 14b used in the first exchange (in steps 21-22), but the downlink packet 15a having the same size s_d as the downlink packet 14a in the first exchange, and sender then determines a second round-trip time t_B. With both t_A and t_B determined, and s_d and s_uA and s_uB known, and also using some predetermined value for the delay d_r between when the receiver 12 receives a first packet 14a 14b and responds with a response packet 15a 15b, the invention makes it possible for the sender to compute the uplink and downlink delays D_u and D_d each separately for a packet of any give size. The step 25 in which this is done—i.e. in which the sender 11 determines the uplink and downlink delays D_u and D_d each separately for a packet of size S—uses two delay formulas, one giving the uplink delay and one giving the downlink delay, as follows:
D_{—}u=S(t_{—}A−t_{—}B)/(s_{—}uA−s_{—}uB), (1)
and
D_{—}d=S[t_{—}B−d_{—}r−((s_{—}uB*(t_{—}A−t_{—}B))/(s_{—}uA−s_{—}uB))]/s_{—}d. (2)
In addition, the invention makes it possible for the sender to compute the uplink and downlink capacities C_u and C_d each separately; this is done in a next step 26 using the following two capacity formulas:
C_{—}u=(s_{—}uA−s_{—}uB)/(t_{—}A−t_{—}B), (3)
and
C_{—}d=s_{—}d/[t_{—}B−d_{—}r−((s_{—}uB*(t_{—}A−t_{—}B))/(s_{—}uA−s_{—}uB))]. (4)

The above-described method is merely one embodiment of the invention. As mentioned, the invention works as long as different-sized packets are used in either the uplink or downlink direction. It should be noted that in the above-described embodiment, if s_uA=s_uB, then denominators in both eqs. (1) and (2) are zero. In another embodiment, instead of using different-sized uplink packets, different sized downlink packets can be used (with the same-sized uplink packets). The corresponding equations can be derived based on the following equations expressing the round trip times for exchanging two pairs of packets:
t_{—}A=s_{—}dA/C_{—}d+s_{—}uA/C_{—}u+d_{—}r, (5)
and
t_{—}B=s_{—}dB/C_{—}d+s_{—}uB/C_{—}u+d_{—}r. (6)
These equations are solved assuming either the downlink packet sizes are the same (s_dA=s_dB), or the uplink packet sizes are the same (s_uA=s_uB), but not both.

In at least some embodiments the above-mentioned data packets are actual messages and so can convey information between the sender and receiver. In such embodiments, in addition to separately providing the uplink and downlink delays and also the uplink and downlink capacities, in case of a protocol where message transfer delays must be known (and so the asymmetric ping procedure of the invention should be carried out), the packets can be used to convey the information the protocol requires be exchanged.

In addition, the uplink and downlink data packets themselves can—in embodiments in which they are actually message—contain information related to the asymmetric ping procedure; e.g. the receiver can include d_r information in at least one of the uplink packets.

Further variants of the invention include exchanging more than two pairs of packets, i.e. where more than two packet transfer transactions (A and B above) are used.

Also, the capacity and delay estimates can be made more reliable by repeating the described procedure more than once in order to collect more statistics and by performing statistical analysis of measurement results (e.g. averaging). Thus, e.g. the (raw) round trip times t_A(1) and t_B(1) of a pair of first exchanges and (raw) round trip times t_A(2) and t_B(2) of a pair of second exchanges would be e.g. simply averaged or combined to form a weighted average (based on some criterion for giving more weight to one of the exchanges than to the other) to yield processed round trip times t_A′ and t_B′. Such statistical analysis can also be used to assess the reliability of the capacity and delay estimates (e.g. by determining standard deviation). This kind of statistical approach helps, for example, to deal with the delay variation encountered in many packet data networks, such as GPRS or TCP/IP networks.

It is also possible to perform the delay and capacity determination procedures and relate some additional quantities to the results, such as time of the day. Thus it is possible to have some estimate of the capacity and delay based on additional quantities even if the actual measurement procedure is not performed. For example, when sufficient measurement results have been collected, and the average capacity and delay depend sufficiently strongly on the time of the day, the delay and capacity can be estimated just using the time of day. Alternatively, it may turn out that a different dynamical quantity than the time of day correlates strongly with the delay and capacity, a dynamical quantity such as both the time of day and the day of the week (or even also the month of the year).

The invention has been described in terms (primarily) of the steps of a method. The invention also comprehends an apparatus for performing the above described steps, an apparatus that is essentially the sender device 11 or included as part of the sender device 11, and, in embodiments in which the receiver device 12 communicates information in the uplink (response) packets 14b 15b, the invention also encompasses an apparatus included in or substantially constituting the receiver device 12. Thus, for each step described above, there can be a corresponding module of an apparatus, although it is also possible for the functionality for performing more than one of the above-described steps to be incorporated into a single module. For example, and referring to FIG. 3, the invention provides a telecommunication terminal 30 including a processor module 31, a clock module 32 for use by the processor module 31 in timing round trips, a packet sender module 33 for sending a (ping) packet (which may include data) and a packet receiver module 34 for receiving a (response) packet (which may also include data). The processor module in turn includes one or more modules for performing the calculations associated with evaluating the round trip times according to eqs. (5) and (6), the uplink and downlink delays per eqs. (1) and (2), and the uplink and downlink capacities per eqs. (3) and (4), or comparable equations in case of exchanges with packets differing in size in different ways than in the exchanges for which eqs. (1)-(6) are valid. Such modules may be implemented as hardware, or may be implemented as software or firmware for execution by a processor. In particular, in the case of firmware or software, the invention is provided as a computer program product including a computer readable storage structure embodying computer program code—i.e. the software or firmware—thereon for execution by a computer processor provided with the sender device 11, and also, for some embodiments, a computer program product for execution by a computer processor provided with the receiver device 12.

Note that the invention can be used to solve the GPS time stamp transfer problem with IP-overlay assisted Global Positioning System solutions.

It is to be understood that the above-described arrangements are only illustrative of the application of the principles of the present invention. Numerous modifications and alternative arrangements may be devised by those skilled in the art without departing from the scope of the present invention, and the appended claims are intended to cover such modifications and arrangements.

1. A method for determining a downlink delay in communicating packets via a packet-conveying network from a sender to a receiver or an uplink delay for communicating packets from the receiver to the sender, or both the downlink delay and also the uplink delay, or for determining uplink or downlink capacities or both, the method comprising:
a step in which the sender and receiver exchange a first pair of packets consisting of a first uplink packet and a first downlink packet and determine a round trip time for the exchange of the first pair of packets; and
a step in which the sender and receiver exchange a second pair of packets consisting of a second uplink packet and a second downlink packet and determine a round trip time for the exchange of the second pair of packets;
wherein at least either the first and second uplink packets or the first and second downlink packets differ in size.

2. The method of claim 1, wherein the steps in which the sender and receiver exchange a pair of packets are repeated with at least either the first and second uplink packets or the first and second downlink packets differing in size, and the round trip times for the respective exchanges are also again determined, and the sender then determines processed round trip times for each of the exchanges by performing a statistical analysis of the round trip times for the respective exchanges.

3. The method of claim 1, further comprising:
a step in which the sender determines for a packet of size S the uplink and downlink delays D_u and D_d, respectively, using:
D_{—}u=S(t_{—}A−t_{—}B)/(s_{—}uA−s_{—}uB),
and
D_{—}d=S[t_{—}B−d_{—}r−((s_{—}uB*(t_{—}A−t_{—}B))/(s_{—}uA−s_{—}uB))]/s_{—}d,
in which d_r is a receiver delay indicating a delay between when the receiver receives one of the downlink packets and when the receiver transmits the corresponding uplink packet in response, t_A is the round trip time for exchanging the first pair of packets of consisting of the first uplink packet having size s_uA and the first downlink packet having size s_d, and in which t_B is the round trip time for exchanging the second pair of packets of consisting of the second uplink packet having size s_uB and the second downlink packet having the same size as the first downlink packet, wherein s_uA is different than s_uB.

4. The method of claim 3, wherein instead of the uplink packets in the first and second exchange of packets differing in size, the downlink packets differ in size.

5. The method of claim 1, further comprising:
a step in which the sender determines the uplink and downlink capacities C_u and C_d, respectively, using:
C_{—}u=(s_{—}uA−s_{—}uB)/(t_{—}A−t_{—}B),
and
C_{—}d=s_{—}d/[t_{—}B−d_{—}r−((s_{—}uB*(t_{—}A−t_{—}B))/(s_{—}uA−s_{—}uB))],
in which t_A is the round trip time for exchanging the first pair of packets consisting of the first uplink packet having size s_uA and the first downlink packet having size s_d, and in which t_B is the round trip time for exchanging the second pair of packets consisting of the second uplink packet having size s_uB and the second downlink packet having the same size as the first downlink packet, wherein s_uA is different than s_uB.

6. The method of claim 5, wherein instead of the uplink packets in the first and second exchange of packets differing in size, the downlink packets differ in size.

7. The method of claim 1 wherein a dynamical quantity is associated with the delay estimates or with the capacity estimates and wherein either the capacities or the delays or both are estimated based on the dynamical quantity using already collected information about the capacities and the delays or both and also using the related dynamical quantity.

8. The method of claim 7 wherein the dynamical quantity is the time of day.

9. The method of claim 7 wherein the dynamical quantity is the time of day and the day of the week.

10. The method of claim 1, wherein at least one of the packets is used to convey information either of use in a predetermined protocol, or of use in determining a receiver delay quantity indicating a delay between when the receiver receives the downlink packet and when the receiver transmits the uplink packet in response.

11. A computer program product comprising: a computer readable storage structure embodying computer program code thereon for execution by a computer processor in a sender device, with said computer program code comprising instructions for performing the steps of the method of claim 1.

12. An apparatus included in a sender device for determining a downlink delay in communicating packets via a packet-conveying network from the sender to a receiver or an uplink delay for communicating packets from the receiver to the sender, or both the downlink delay and also the uplink delay, or for determining uplink or downlink capacities or both, the apparatus comprising:
means by which the sender and receiver exchange a first pair of packets consisting of a first uplink packet and a first downlink packet and determine a round trip time for the exchange of the first pair of packets; and
means by which the sender and receiver exchange a second pair of packets consisting of a second uplink packet and a second downlink packet and determine a round trip time for the exchange of the second pair of packets;
wherein at least either the first and second uplink packets or the first and second downlink packets differ in size.

13. The apparatus of claim 12, wherein the means by which the sender and receiver exchange a pair of packets repeats the exchange at least once with at least either the first and second uplink packets or the first and second downlink packets differing in size for each exchange, and also again determines the round trip times for the respective exchanges, and then determines processed round trip times for each of the exchanges by performing a statistical analysis of the round trip times for the respective exchanges.

14. The apparatus of claim 12, further comprising:
means by which the sender determines for a packet of size S the uplink and downlink delays D_u and D_d, respectively, using:
D_{—}u=S(t_{—}A—t_{—}B)/(s_{—}uA−s_{—}uB),
and
D_{—}d=S[t_{—}B−d_{—}r−((s_{—}uB*(t_{—}A−t_{—}B))/(s_{—}uA−s_{—}uB))]/s_{—}d,
in which d_r is a receiver delay indicating a delay between when the receiver receives one of the downlink packets and when the receiver transmits the corresponding uplink packet in response, t_A is the round trip time for exchanging the first pair of packets of consisting of the first uplink packet having size s_uA and the first downlink packet having size s_d, and in which t_B is the round trip time for exchanging the second pair of packets of consisting of the second uplink packet having size s_uB and the second downlink packet having the same size as the first downlink packet, wherein s_uA is different than s_uB.

15. The apparatus of claim 14, wherein instead of the uplink packets in the first and second exchange of packets differing in size, the downlink packets differ in size.

16. The apparatus of claim 12, further comprising:
means by which the sender determines the uplink and downlink capacities C_u and C_d, respectively, using:
C_{—}u=(s_{—}uA−s_{—}uB)/(t_{—}A−t_{—}B),
and
C_{—}d=s_{—}d/[t_{—}B−d_{—}r−((s_{—}uB*(t_{—}A−t_{—}B))/(s_{—}uA−s_{—}uB))],
in which t_A is the round trip time for exchanging the first pair of packets consisting of the first uplink packet having size s_uA and the first downlink packet having size s_d, and in which t_B is the round trip time for exchanging the second pair of packets consisting of the second uplink packet having size s_uB and the second downlink packet having the same size as the first downlink packet, wherein s_uA is different than s_uB.

17. The apparatus of claim 16, wherein instead of the uplink packets in the first and second exchange of packets differing in size, the downlink packets differ in size.

18. The apparatus of claim 12 wherein a dynamical quantity is associated with the delay estimates or with the capacity estimates and wherein either the capacities or the delays or both are estimated based on the dynamical quantity using already collected information about the capacities and the delays or both and also using the related dynamical quantity.

19. The apparatus of claim 18 wherein the dynamical quantity is the time of day.

20. The apparatus of claim 18 wherein the dynamical quantity is the time of day and the day of the week.

21. The apparatus of claim 12, wherein at least one of the packets is used to convey information either of use in a predetermined protocol, or of use in determining a receiver delay quantity indicating a delay between when the receiver receives the downlink packet and when the receiver transmits the uplink packet in response.

22. A system, comprising a telecommunication network, and a sender device and a receiver device communicatively coupled thereby, the sender including an apparatus as in claim 12.
